(19) United States
(12) Patent Application Publication
(10) Pub. No.: US 2025/0081327 A1
(43) Pub. Date: Mar. 6, 2025

(54) NON-CONTACT COOLING ASSEMBLY FOR COOLING SUBSTRATES

(71) Applicant: ASM IP Holding B.V., Almere (NL)

(72) Inventor: Mandar Deshpande, Phoenix, AZ (US)

(21) Appl. No.: 18/813,147

(22) Filed: Aug. 23, 2024

Related U.S. Application Data
(60) Provisional application No. 63/535,605, filed on Aug. 31, 2023.

(51) Int. Cl. H05K 1/02

(52) U.S. Cl. CPC H05K 1/0204; H05K 2201/064

(57) ABSTRACT

A non-contact cooling assembly for cooling substrates in equipment front end module in batch is presented. The cooling assembly may comprise a support beam and a plurality of cooling plates, wherein the cooling plates are arranged horizontally stacked and attached to the support beam, and wherein the support beam is configured to move horizontally for cooling substrates. Each of the cooling plates may utilize either thermoelectric cooling effect or cooling fluid for cooling the cooling plates and a cooling plate is placed at a first position (distal position) at first and it moves to a second position (proximal position) for more effective substrate cooling.

### CROSS-REFERENCE TO RELATED APPLICATION(S)

This Application claims the benefit of U.S. Provisional Application 63/535,605 filed on Aug. 31, 2023, the entire contents of which are incorporated herein by reference.

### FIELD OF INVENTION

The present disclosure relates to a substrate cooling assembly, particularly to non-contact cooling assembly for substrates in batch.

### BACKGROUND OF THE DISCLOSURE

During substrate processing, substrates are heated by high reaction temperatures and chemical reactions. Usually, these hot substrates are placed in cassette shelf structure in equipment front end module (EFEM) to be cooled via forced air convention cooling.

The substrates need to be cooled down to safe handling temperature and this temperature usually may be prescribed beforehand.

The substrates need a backside access to allow an effector to pick up the substrates and also a top side clearance to allow the substrate pick up operation. Therefore, the need for access and clearance would restrict any cooling devices presence in the area.

Therefore, the present disclosure presents a substrate cooling assembly to simultaneously cool multiple substrates.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a non-contact cooling assembly for cooling substrates in equipment front end module in batch, the assembly comprising: a support beam; and a plurality of cooling plates, wherein the cooling plates are arranged horizontally stacked and attached to the support beam, wherein the support beam is configured to move horizontally for cooling substrates.

In at least one aspect, each of the cooling plates comprising: a top substrate; alternating p & n-type semiconductor pillars configured to be placed thermally in parallel to each other and electrically in series; thermally conducting plates configured to join the alternating p & n-type semiconductor pillars; and a down substrate.

In at least one aspect, each of the cooling plates comprising: a thermally conducting plate; and micro-channels placed in the thermally conducting plate, wherein a cooling fluid flow through the micro-channels for cooling the thermally conducting plate.

In at least one aspect, at least one of the cooling plates comprising, a top substrate; alternating p & n-type semiconductor pillars configured to be placed thermally in parallel to each other and electrically in series; thermally conducting plates configured to join the alternating p & n-type semiconductor pillars; and a down substrate, and at least one of the cooling plates comprising: a thermally conducting plate; and micro-channels placed in the thermally conducting plate, wherein a cooling fluid flow through the micro-channels for cooling the thermally conducting plate.

In at least one aspect, each of the cooling plates configured to be placed in a very close proximal position of a substrate top when the cooling assembly is in a substrate shelf for cooling substrates.

In at least one aspect, the support beam configured to move vertically.

In at least one aspect, the cooling plates' shape is one of circle, ellipse, or any polygon with equal to or more than 4 angles.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1a illustrates a front view of a cooling assembly according to an embodiment of the present disclosure.

FIG. 1b illustrates a top-down view of a cooling assembly according to an embodiment of the present disclosure.

FIG. 2 illustrates a cooling plate perspective view in a cooling assembly according to an embodiment of the present disclosure.

FIG. 3 illustrates a cooling plate view in a cooling assembly according to another embodiment of the present disclosure.

FIG. 4a illustrates a front view of a cooling assembly before it is inserted into a substrate shelf according to an embodiment of the present disclosure.

FIG. 4b illustrates a front view of a cooling assembly after it is inserted into a substrate shelf for cooling the wafers according to an embodiment of the present disclosure.

FIG. 5a illustrates a front view of a cooling assembly before it is inserted into a substrate shelf according to another embodiment of the present disclosure.

FIG. 5b illustrates a front view of a cooling assembly when it is positioned to a cooling position for the upper substrates in a substrate shelf according to another embodiment of the present disclosure.

FIG. 5c illustrates a front view of a cooling assembly when it is positioned to a cooling position for the lower substrates in a substrate shelf according to another embodiment of the present disclosure.

FIG. 6a) illustrates a front view of a cooling assembly when it is positioned to a cooling position for the upper substrates in a substrate shelf according to another embodiment of the present disclosure.

FIG. 6b illustrates a detailed view of a cooling assembly when it is positioned to a first position (distal position) from a wafer according to another embodiment of the present disclosure.

FIG. 6(c) illustrates a detailed view of a cooling assembly when it is positioned to a second position (proximal position) from a wafer according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

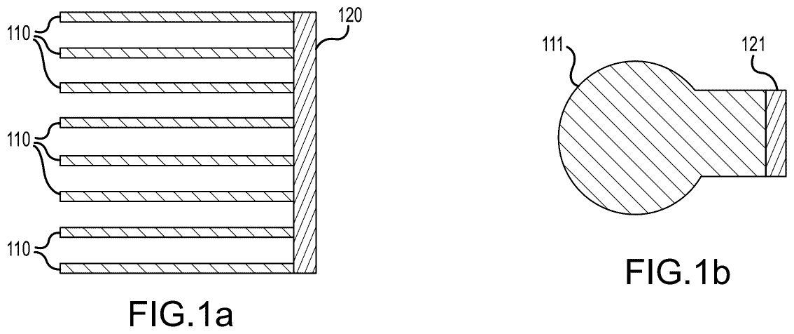

FIG. 1a illustrates a front view of a cooling assembly according to an embodiment of the present disclosure.

In this front view illustrates that the cooling assembly may comprise a plurality of cooling plates 110 and a support beam 120. The cooling plates may be arranged horizontally stacked and attached to the support beam 120.

FIG. 1b illustrates a top-down view of the cooling assembly and in this figure only the top cooling plate 111 and the support beam 121 it may be attached to may be shown. The shape of the cooling plate could be a circle or an ellipse, or polygons with equal to or more than 4 angles such as tetragon, pentagon, hexagon, etc., . . . , i.e., a shape which could cover in its entirety the wafer it needs to cool down.

Therefore, although FIG. 1b shows only circle for the shape of cooling plate 111, other shapes like tetragon or hexagon could be used. When need arises, each cooling plate in the plurality of cooling plates could have different shapes.

The cooling plates must be cooled down to cool down the wafers and they need to be placed in a very close proximity of the wafers they want to cool down.

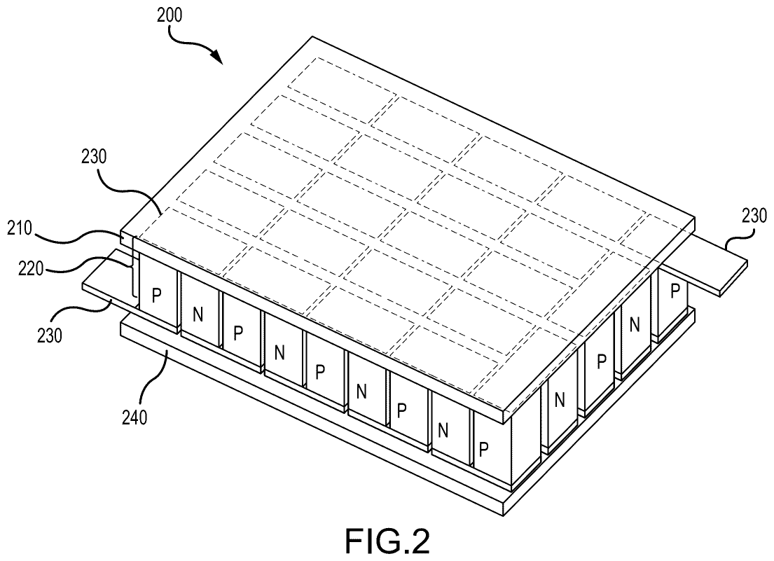

FIG. 2 shows a cooling plate with a way to cool down the cooling plate in an embodiment of the present disclosure.

Each of the cooling plates 200 comprises a top substrate 210, a down substrate 240, alternatingly placed p & n-type semiconductor pillars 220 between the top substrate 210 and the down substrate 240, thermally conducting plates 230 configured to join the p & n-type semiconductor pillars 220 between the p & n-type semiconductor pillars 220 and the top substrate 210 and between the p & n-type semiconductor pillars 220 and the down substrate 240 thermally in parallel to each other and electrically in series.

The cooling plate above has a hot substrate (top substrate 210) and cold substrate (down substrate 240) by a solid-state cooling method (i.e. thermoelectric cooling effect). The thermoelectric cooling effect (Peltier effect) is a well-known effect and will not be explained in detail in this specification.

When a DC electric current flows through the device, it brings heat from the down substrate 240 to the top substrate 210, so that down substrate 240 gets cooler while the top substrate 210 gets hotter.

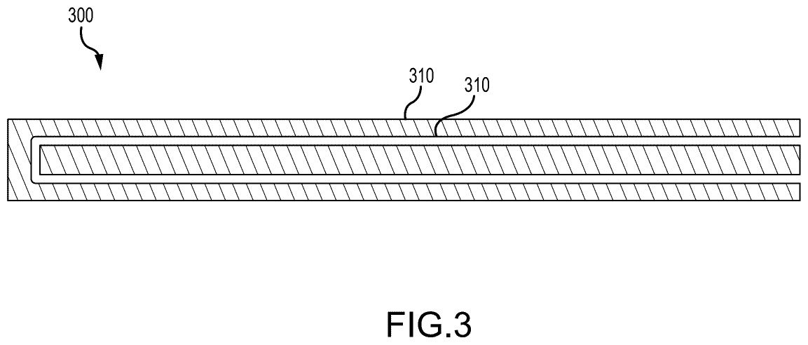

FIG. 3 illustrates a cooling plate 300 with a way to cool down the cooling plate in another embodiment of the present disclosure.

In this embodiment, each of the cooling plates 300 comprises a thermally conducting plate 310 and micro-channels 320. The micro-channels 320 may be placed in the conducting plate 310 and a cooling fluid flows through it for cooling the conducting plate 310.

FIG. 2 and FIG. 3 illustrate two different cooling principles. But, by cooling down the cooling plates (200, 300) and placing them in proximity of the hot wafer, the present disclosure's cooling assembly can cool down the hot wafer effectively.

In an embodiment, the cooling assembly may comprise a support beam and a plurality of cooling plates, each of the cooling plates comprises a top substrate, alternating p & n-type semiconductor pillars configured to be placed thermally in parallel to each other and electrically in series, thermally conducting plates configured to join the alternating p & n-type semiconductor pillars, and a down substrate as illustrated in FIG. 2.

In another embodiment, the cooling assembly may comprise a support beam and a plurality of cooling plates, each of the cooling plates comprises a thermally conducting plate; and micro-channels placed in the thermally conducting plate, wherein a cooling fluid flow through the micro-channels for cooling the thermally conducting plate as illustrated in FIG. 3.

In another embodiment, the cooling assembly may comprise a support beam and a plurality of cooling plates, at least one of the cooling plates comprises a thermally conducting plate; and micro-channels placed in the thermally conducting plate, wherein a cooling fluid flow through the micro-channels for cooling the thermally conducting plate as illustrated in FIG. 3 and at least one of the cooling plates comprises a top substrate, alternating p & n-type semiconductor pillars configured to be placed thermally in parallel to each other and electrically in series, thermally conducting plates configured to join the alternating p & n-type semiconductor pillars, and a down substrate as illustrated in FIG. 2. In this case, two different cooling mechanisms are employed in the cooling plates at the same time.

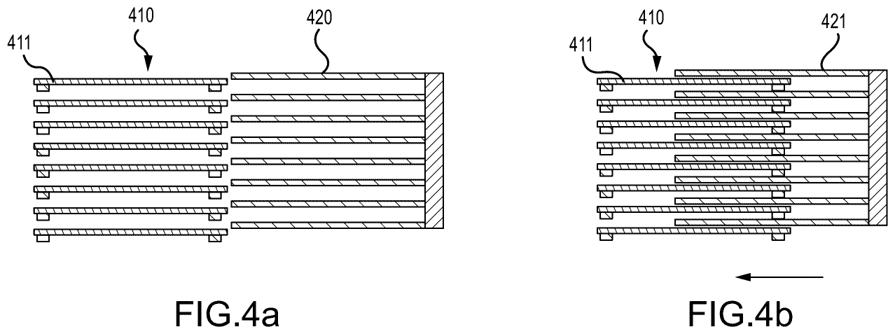

In FIG. 4a, the height of a substrate shelf 410 on which a substrate 411 is placed may be equal to that of the cooling assembly 420. In this case, just like in FIG. 4b, the cooling assembly 421 does not need to move vertically and it would just need to move horizontally.

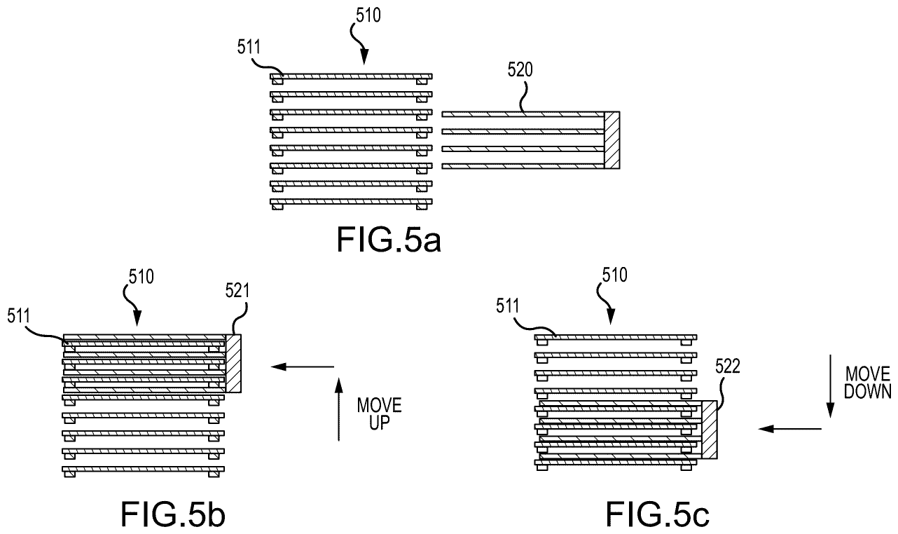

In FIG. 5a, the height of a substrate shelf 510 on which a substrate 511 is placed may be larger than that of the cooling assembly 520. So, if the wafers placed on the upper part of the substrate shelf 510 need to be cooled down, the cooling assembly 521 may need to move up vertically and then move horizontally. And if the wafers placed on the lower part of the substrate shelf 510 need to be cooled down, the cooling assembly 522 may need to move down vertically first and then move horizontally.

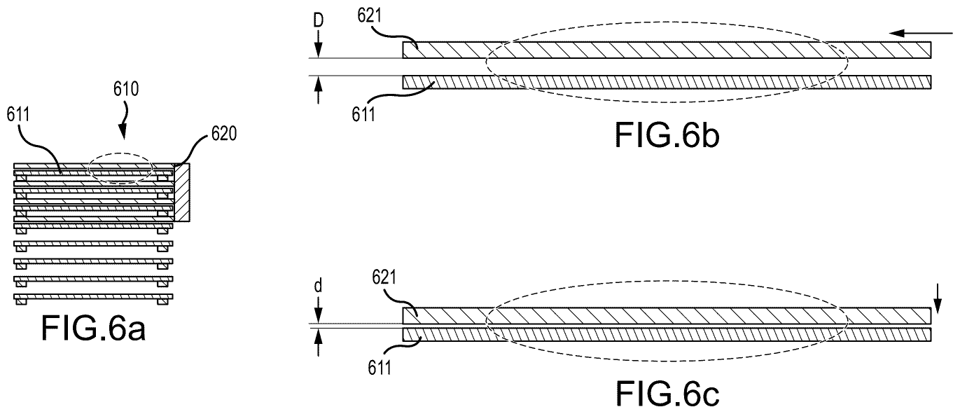

There may be another aspect for the movement of the cooling assembly. In FIG. 6a illustrates a case when a cooling assembly 620 may be inserted into a substrate shelf 610 on which a substrate 611 is placed. When viewed in detail in FIG. 6b, when the cooling assembly 620 may be inserted at first, the cooling plate 621 which may be used to cool down the substrate 611 may be placed at a distance ‘D’ which may be a distal position (first position).

But for an efficient cooling, the cooling plate may need to move to a closer position than the first position. For this purpose, the cooling plate 621 (along with the cooling assembly) may move downward a little to be in a very close proximity of the wafer 611.

Finally, the cooling plate 621 is at a second position (proximal position) with a distance ‘d’ from the wafer 611 where (d<D) (In FIG. 6c).

This adjusting vertical movement (movement from first position to second position) may take place when the height of a substrate shelf is larger than that of a cooling assembly (FIG. 5a) as well as when the height of a substrate shelf is equal to that of a cooling assembly (FIG. 4a).

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A non-contact cooling assembly for cooling substrates in equipment front end module in batch, the cooling assembly comprising:
a support beam; and
a plurality of cooling plates, wherein the cooling plates are arranged horizontally stacked and attached to the support beam,
wherein the support beam is configured to move horizontally for cooling substrates.

2. The cooling assembly according to claim 1, wherein
each of the cooling plates comprising:
a top substrate;
alternating p & n-type semiconductor pillars configured to be placed thermally in parallel to each other and electrically in series;
thermally conducting plates configured to join the alternating p & n-type semiconductor pillars; and
a down substrate.

3. The cooling assembly according to claim 1, wherein
each of the cooling plates comprising:
a thermally conducting plate; and
micro-channels placed in the thermally conducting plate, wherein a cooling fluid flow through the micro-channels for cooling the thermally conducting plate.

4. The cooling assembly according to claim 1, wherein
at least one of the cooling plates comprising,
a top substrate;
alternating p & n-type semiconductor pillars configured to be placed thermally in parallel to each other and electrically in series;
thermally conducting plates configured to join the alternating p & n-type semiconductor pillars; and
a down substrate,
and
at least one of the cooling plates comprising:
a thermally conducting plate; and
micro-channels placed in the thermally conducting plate, wherein a cooling fluid flow through the micro-channels for cooling the thermally conducting plate.

5. The cooling assembly according to claim 2, wherein
each of the cooling plates configured to be placed in a very close proximal position of a substrate top when the cooling assembly is in a substrate shelf for cooling substrates.

6. The cooling assembly according to claim 1, wherein
the support beam configured to move vertically.

7. The cooling assembly according to claim 1, wherein
shape of each of the cooling plates is one of circle, ellipse, or a polygon with four or more angles.
